(19) United States
(12) Patent Application Publication
(10) Pub. No.: US 2020/0126801 A1
(43) Pub. Date: Apr. 23, 2020

(54) ETCHING METHOD AND PLASMA PROCESSING APPARATUS

(71) Applicant: TOKYO ELECTRON LIMITED, Tokyo (JP)

(72) Inventors: Maju TOMURA, Miyagi (JP); Yoshihide KIHARA, Miyagi (JP); Masanobu HONDA, Miyagi (JP)

(73) Assignee: TOKYO ELECTRON LIMITED, Tokyo (JP)

(21) Appl. No.: 16/560,327

(22) Filed: Sep. 4, 2019

(30) Foreign Application Priority Data
Oct. 22, 2018 (JP) 2018-198241

(51) Int. Cl. H01L 21/3065; H01L 21/3213; H01L 21/67; H01L 21/263

(52) U.S. Cl. CPC H01L 21/3065; H01L 21/2633; H01L 21/67207; H01L 21/32137

(57) ABSTRACT

A method of etching a silicon-containing film includes providing a workpiece in a chamber body of a plasma processing apparatus. The workpiece has a silicon-containing film and a mask. The mask is provided on the silicon-containing film. An opening is formed in the mask. The etching method further includes etching a silicon-containing film. In the etching, plasma of a processing gas containing carbon and iodine heptafluoride is generated in the chamber body to etch the silicon-containing film.

### CROSS-REFERENCE TO RELATED APPLICATIONS

This application is based on and claims priority from Japanese Patent Application No. 2018-198241, filed on Oct. 22, 2018 with the Japan Patent Office, the disclosure of which is incorporated herein in its entirety by reference.

### TECHNICAL FIELD

Embodiments disclosed herein relate to an etching method and a plasma processing apparatus.

### BACKGROUND

In the manufacture of electronic devices, an etching of a silicon-containing film is performed using plasma. The silicon-containing film is formed of a silicon-containing material such as, for example, silicon oxide or silicon nitride. For example, in the manufacture of a NAND flash memory having a three-dimensional structure, etching of a multilayer film including a plurality of silicon oxide films and a plurality of silicon nitride films, which are alternately stacked, as a silicon-containing film, is performed. In the etching of a silicon-containing film, a mask containing carbon such as amorphous carbon is used as a mask. An opening is formed in the mask.

In the etching of a silicon-containing film, it is required that the silicon-containing film is etched in the film thickness direction. That is, a high verticality is required for etching a silicon-containing film. In order to obtain a high verticality, US Patent Publication No. 2016/0343580 describes a technique for protecting a side wall surface that defines an opening formed by etching. Specifically, in one technique described in US Patent Publication No. 2016/0343580, a silicon-containing film is etched by plasma of fluorocarbon gas. In this technique, the silicon-containing film is etched by the active species of fluorine generated from the fluorocarbon gas while the side wall surface is protected by a carbon-containing material generated from the fluorocarbon gas. In another technique described in US Patent Publication No. 2016/0343580, etching by active species of fluorine generated from fluorocarbon gas and formation of a protective film by a film forming process are alternately performed.

### SUMMARY

In an embodiment, a method for etching a silicon-containing film is proved. The etching method includes providing a workpiece in a chamber body of a plasma processing apparatus. The workpiece has a silicon-containing film and a mask. The mask is provided on the silicon-containing film. An opening is formed in the mask. The etching method further includes etching a silicon-containing film. In the etching, plasma of a processing gas containing carbon and iodine heptafluoride is generated in the chamber body to etch the silicon-containing film.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flow chart illustrating an etching method according to an embodiment.

FIG. 2 is a partially enlarged cross-sectional view illustrating an exemplary workpiece to which the etching method shown in FIG. 1 is applicable.

FIG. 3 is a view illustrating an exemplary plasma processing apparatus capable of being used to execute the etching method illustrated in FIG. 1.

FIG. 4 is a partially enlarged cross-sectional view illustrating an exemplary workpiece after the etching method illustrated in FIG. 1 was applied thereto.

FIG. 5 is a graph representing a simulation result.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, various embodiments will be described.

In an embodiment, a method for etching a silicon-containing film is provided. The etching method includes a step of providing a workpiece in a chamber body of a plasma processing apparatus. The workpiece has a silicon-containing film and a mask. The mask is provided on the silicon-containing film. An opening is formed in the mask. The etching method further includes a step of etching a silicon-containing film. In the etching step, plasma of a processing gas containing carbon and iodine heptafluoride is generated inside the chamber body to etch the silicon-containing film.

In the etching method according to the embodiment, a side wall surface of the silicon-containing film formed by etching is protected by a protective material. The protective material includes an iodide such as silicon iodide formed from silicon in the silicon-containing film and iodine in the processing gas, and has high resistance to fluorine active species. Therefore, according to this etching method, lateral etching of the silicon-containing film is suppressed.

In an embodiment, the processing gas may include iodine heptafluoride. The ratio of the flow rate of the iodine heptafluoride gas to the total flow rate of the processing gas supplied into the chamber body in the step of etching the silicon-containing film may be 1.3% or more.

In an embodiment, the processing gas may further contain fluorine.

In an embodiment, the step of etching the silicon-containing film includes a step of partially etching the silicon-containing film by the plasma of the processing gas including a fluorine-containing gas. The step of etching the silicon-containing film further includes a step of further etching the silicon-containing film by the plasma of the processing gas further including an additive gas. The additive gas contains molecules including fluorine. The bonding energy of fluorine in the molecules included in the additive gas is lower than the bonding energy of fluorine in the molecules in the fluorine-containing gas. In this embodiment, when the depth of the opening formed in the silicon-containing film by etching is increased, the additive gas is added to the processing gas. The additive gas generates fluorine active species having a small mass more than the fluorine-containing gas in the processing gas. The fluorine active species having a small mass is likely to reach a deep point in the opening. Therefore, according to this embodiment, a decrease in the etching rate of the silicon-containing film is suppressed.

In an embodiment, the step of further etching the silicon-containing film is performed when the aspect ratio of the opening formed in the silicon-containing film is 40 or more. In another embodiment, the step of further etching the silicon-containing film is initiated depending on the emission intensity of a wavelength corresponding to the silicon of emission of the plasma generated in the chamber body during the step of partially etching the silicon-containing film. In this embodiment, the step of further etching the silicon-containing film is initiated when it is determined that no silicon is released from the silicon-containing film based on the emission intensity of the wavelength corresponding to the silicon.

In an embodiment, the silicon-containing film is formed of at least one of silicon oxide and silicon nitride. In an embodiment, the silicon-containing film includes a plurality of silicon oxide films and a plurality of silicon nitride films, which are alternately stacked.

In an embodiment, the mask contains carbon. In this embodiment, since iodine in the processing gas reacts with carbon and fluorine to form a volatile compound, blocking of the opening in the mask is suppressed. In another embodiment, the mask contains tungsten. In this embodiment, etching of the mask by fluorine is suppressed.

In another embodiment, a plasma processing apparatus is provided. The plasma processing apparatus includes a chamber body, a support, a radio-frequency power supply, and a controller. The support is provided in the chamber body. The gas supply is configured to supply a processing gas containing carbon and iodine heptafluoride into the chamber body. The radio-frequency power supply is configured to supply radio-frequency power to excite the progressing gas. The controller is configured to control the gas supply and the radio-frequency power supply. The controller is configured to: execute control of the gas supply to supply the processing gas into the chamber body to etch a silicon-containing film of a workpiece disposed on the support by generating plasma of the processing gas, and execute a control of the radio-frequency power supply to supply the radio-frequency power.

In an embodiment, the processing gas may include iodine heptafluoride gas. In the control of the gas supply, the controller may adjust a ratio of a flow rate of the iodine heptafluoride gas to a total flow rate of the processing gas supplied into the chamber body to 1.3% or more.

In an embodiment, the processing gas may further contain fluorine.

In an embodiment, the controller may execute a first control and a second control in the control of the gas supply. In the first control, the controller causes the gas supply to supply the processing gas including a fluorine-containing gas into the chamber body. In the second control, the controller causes the gas supply to supply the processing gas further including an additive gas into the chamber body. The additive gas contains molecules including fluorine. The bonding energy of fluorine in the molecules included in the additive gas is lower than the bonding energy of fluorine in the molecules in the fluorine-containing gas.

In an embodiment, the controller may execute the second control when the aspect ratio of the opening formed in the silicon-containing film SF is 40 or more. In another embodiment, the controller may initiate the second control when it is determined that no silicon is released from the silicon-containing film based on emission intensity of a wavelength corresponding silicon of emission of the plasma generated in the chamber body during execution of the first control.

Hereinafter, various embodiments will be described in detail with reference to the drawings. In each of the drawings, the same or corresponding components will be denoted by the same reference numerals.

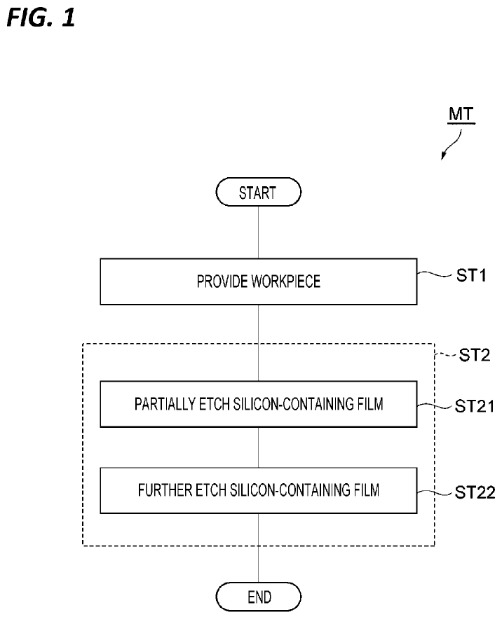

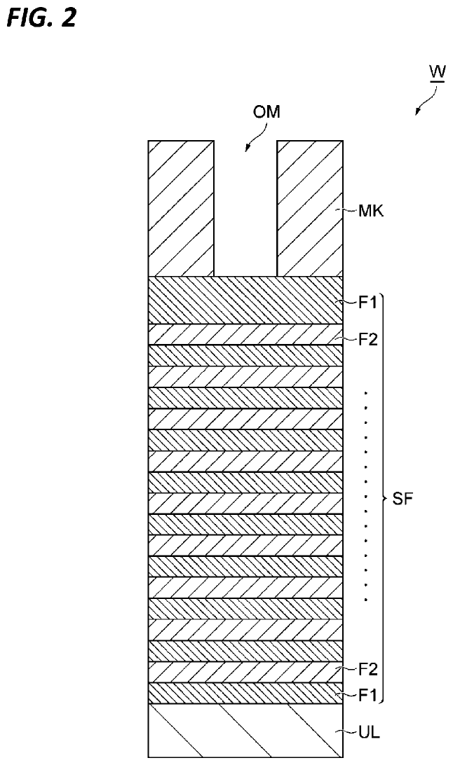

FIG. 1 is a flow chart illustrating an etching method according to an embodiment. The etching method illustrated in FIG. 1 (hereinafter referred to as a “method MT”) is performed to etch a silicon-containing film. FIG. 2 is a partially enlarged cross-sectional view illustrating an exemplary workpiece to which the etching method shown in FIG. 1 is applicable. The exemplary workpiece W illustrated in FIG. 2 has a mask MK and a silicon-containing film SF. The silicon-containing film SF may be provided on an underlayer UL.

The silicon-containing film SF may be formed of any silicon-containing material. In an embodiment, the silicon-containing film SF may be formed of at least one of silicon oxide and silicon nitride. In an example, the silicon-containing film SF includes a plurality of first films F1 and a plurality of second films F2, as illustrated in FIG. 2. The plurality of first films F1 and the plurality of second films F2 are alternately stacked to constitute a multilayer film. The plurality of first films F1 are formed of silicon oxide. The plurality of second films F2 are formed of silicon nitride. That is, the workpiece W has a plurality of silicon oxide films and a plurality of silicon nitride films which are stacked alternately. In the example illustrated in FIG. 2, the first film F1 is the lowermost film in the multilayer film provided directly on the underlayer UL. However, the second film F2 may be the lowermost film in the multilayer film provided directly on the underlayer UL. In the example illustrated in FIG. 2, the first film F1 is the uppermost film in the multilayer film provided immediately below the underlayer UL. However, the second film F2 may be the uppermost film in the multilayer film provided immediately below the mask MK.

The mask MK is provided on the silicon-containing film SF. In an embodiment, the mask MK may be formed of a carbon-containing material. The mask MK may be formed of, for example, amorphous carbon. Alternatively, the mask MK may be formed of a material containing tungsten. The mask MK may be formed of, for example, tungsten. The mask MK may be formed of any material having resistance to etching of the silicon-containing film SF. An opening OM is formed in the mask MK. The opening OM partially exposes the surface of the silicon-containing film SF. The opening OM is a hole or a trench. In the method MT, the pattern of the mask MK is transferred to the silicon-containing film SF by plasma etching.

Reference is again made to FIG. 1. Hereinafter, the method MT will be described with reference to the case where the method MT is applied to the workpiece W illustrated in FIG. 2 as an example. However, the workpiece to which the method MT is applied is not limited to the workpiece illustrated in FIG. 2.

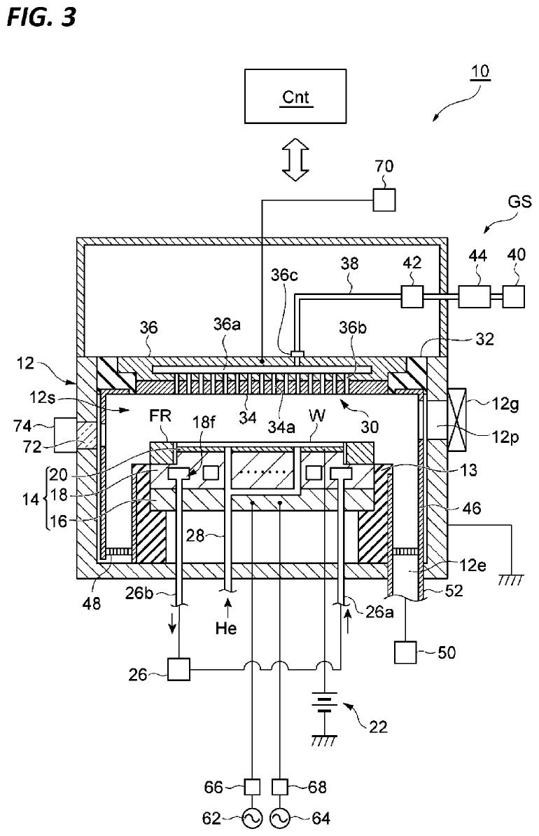

As illustrated in FIG. 1, in the method MT, step ST1 is performed. In step ST1, the workpiece W is provided in the chamber body of a plasma processing apparatus. FIG. 3 is a view illustrating an exemplary plasma processing apparatus capable of being used to execute the etching method illustrated in FIG. 1. The plasma processing apparatus 10 illustrated in FIG. 3 is a capacitively coupled plasma etching apparatus. The plasma etching apparatus 10 includes a chamber body 12. The chamber body 12 has a substantially cylindrical shape, and provides an internal space 12s. The chamber body 12 is made of, for example, aluminum. The inner wall surface of the chamber body 12 is processed to have plasma resistance. For example, the inner wall surface of the chamber body 12 is anodized. The chamber body 12 is electrically grounded.

A passage 12p is formed in the side wall of the chamber body 12. The workpiece W passes through the passage 12p when being carried into the internal space 12s and when being carried out of the internal space 12s. The passage 12p is configured to be capable of being opened/closed by a gate valve 12g.

A support 13 is provided on the bottom portion of the chamber body 12. The support 13 is formed of an insulating material. The support 13 has a substantially cylindrical shape. The support 13 extends in the vertical direction from the bottom portion of the chamber body 12 in the internal space 12s. The support 13 supports a stage 14. The stage 14 is provided in the internal space 12s.

The stage 14 has a lower electrode 18 and an electrostatic chuck 20. The stage 14 may further include an electrode plate 16. The electrode plate 16 is formed of, for example, a conductive material such as, for example, aluminum, and has a substantially disk shape. The lower electrode 18 is provided on the electrode plate 16. The lower electrode 18 is made of, for example, a conductive material such as, for example, aluminum, and has a substantially disk shape. The lower electrode 18 is electrically connected to the electrode plate 16.

The electrostatic chuck 20 is provided on the lower electrode 18. The workpiece W is placed on the upper surface of the electrostatic chuck 20. The electrostatic chuck 20 has a body formed of a dielectric. In the body of the electrostatic chuck 20, a film-shaped electrode is provided. The electrode of the electrostatic chuck 20 is connected to a DC power supply 22 via a switch. When a voltage from a DC power supply 22 is applied to the electrode of the electrostatic chuck 20, an electrostatic attractive force is generated between the electrostatic chuck 20 and the workpiece W. The workpiece W is attracted to the electrostatic chuck 20, and held by the electrostatic chuck 20 by the generated electrostatic attractive force.

A focus ring FR is disposed on the stage 14 to surround the edge of the workpiece W. The focus ring FR is provided to improve the in-plane uniformity of etching. The focus ring FR may be formed of, but not limited to, silicon, silicon carbide, or quartz.

Inside the lower electrode 18, a flow path 18f is provided. A coolant is supplied to the flow path 18f from a chiller unit 26 provided outside the chamber body 12 through a pipe 26a. The coolant supplied to the flow path 18f returns to the coolant unit 26 via the coolant pipe 26b. In the plasma processing apparatus 10, the temperature of the workpiece W disposed on the electrostatic chuck 20 is adjusted by heat exchange between the coolant and the lower electrode 18.

The plasma processing apparatus 10 is provided with a gas supply line 28. A gas supply line 28 supplies a heat transfer gas such as, for example, He gas, from the heat transfer gas supply mechanism to a gap between the upper surface of the electrostatic chuck 20 and the rear surface of the workpiece W.

The plasma processing apparatus 10 further includes an upper electrode 30. The upper electrode 30 is provided above the stage 14. The upper electrode 30 is supported in the upper portion of the chamber body 12 though a member 32. The member 32 is formed of a material having an insulating property. The upper electrode 30 may include a ceiling plate 34 and a support 36. The lower surface of the ceiling plate 34 is the lower surface on the internal space 12s side, and defines the internal space 12s. The ceiling plate 34 may be formed of a low-resistance conductor or a semiconductor with low Joule heat. The ceiling plate 34 is provided with a plurality of gas ejection holes 34a. The plurality of gas ejection holes 34a penetrate the ceiling plate 34 in the thickness direction thereof.

The support 36 detachably supports the electrode plate 34, and may be formed of a conductive material such as, for example, aluminum. A gas diffusion chamber 36a is provided inside the support 36. A plurality of gas flow holes 36b communicating with the gas ejection ports 34a extend downward from the gas diffusion chamber 36a. The electrode 36 has a gas inlet 39 formed therein to guide the processing gas to the gas diffusion chamber 36a. A gas supply pipe 38 is connected to each gas inlet 36c.

A gas supply GS is connected to the gas supply pipe 38. In an embodiment, the gas supply GS includes a gas source group 40, a valve group 42, and a flow rate controller group 44. The gas source group 40 is connected to the gas supply pipe through the flow rate controller group 44 and the valve group 42. The gas source group 40 includes a plurality of gas sources. The gas sources include sources of a plurality of gases forming a processing gas used in the method MT. The valve group 42 includes a plurality of opening/closing valves. The flow rate controller group 44 includes a plurality of flow rate controllers. Each of the flow rate controllers is a mass flow controller or a pressure control-type flow rate controller. The gas sources of the gas source group 40 are connected to the gas supply pipe 38 through a corresponding valve of the valve group 42 and a corresponding flow rate controller of the flow rate controller group 44.

In the plasma processing apparatus 10, a shield 46 is detachably installed along the inner wall of the chamber body 12. The shield 46 is also installed on the outer periphery of the support 13. The shield 46 suppresses etching byproducts from adhering to the processing container 12. The shield 46 is configured by coating, for example, an aluminum member with ceramic such as, for example, Y₂O₃.

A baffle plate 48 is provided between the support 13 and the side wall of the chamber body 12. The baffle plate 48 is configured by coating, for example, an aluminum member with ceramic such as, for example, Y₂O₃. A plurality of through holes are formed in the baffle plate 48. An exhaust port 12e is provided below the baffle plate 48 and in the bottom portion of the chamber body 12. An exhaust apparatus 50 is connected to the exhaust port 12e via an exhaust pipe 52. The exhaust apparatus 50 includes a pressure control valve and a vacuum pump such as, for example, a turbo molecular pump.

The plasma processing apparatus 10 further includes a first radio-frequency power supply 62 and a second radio-frequency power supply 64. The first radio-frequency power supply 62 is a power supply that generates first radio-frequency waves (radio-frequency power) for plasma generation. The frequency of the first radio-frequency waves is in the range of, for example, 27 MHz to 100 MHz. The first radio-frequency power supply 62 is connected to the lower electrode 18 via a matcher 66 and the electrode plate 16. The matcher 66 has a circuit configured to match the output impedance of the first radio-frequency power supply 62 with the input impedance on the load side (the lower electrode 18 side). In addition, the first radio-frequency power supply 62 may be connected to the upper electrode 30 via the matcher 66.

The second radio-frequency power supply 64 is a power supply configured to generate second radio-frequency waves (another radio-frequency power) for drawing ions into a workpiece W. The frequency of the second radio-frequency waves is lower than the frequency of the first radio-frequency waves. The frequency of the second radio-frequency waves is in the range of, for example, 400 kHz to 13.56 MHz. The second radio-frequency power supply 64 is connected to the lower electrode 18 via a matcher 68 and the electrode plate 16. The matcher 68 has a circuit configured to match the output impedance of the second radio-frequency power supply 64 with the input impedance on the load side (the lower electrode 18 side).

The plasma processing apparatus 10 may further include a direct current (DC) power supply 70. The DC power supply 70 is connected to the upper electrode 30. The DC power supply 70 is capable of generating a negative DC voltage and applying the DC voltage to the upper electrode 30.

The side wall of the chamber body 12 is provided with an optical window 72. The optical window 72 is formed of a material transparent to light from plasma generated in the internal space 12s. The optical window 72 is formed of, for example, quartz. A spectroscopic analyzer 74 is provided on the outside of the chamber body 12 to face the optical window 72. The spectroscopic analyzer 74 is configured to measure the spectrum of light received through the optical window 72, i.e., the spectrum of the emission of plasma, and output spectrum data representative of the spectrum.

The plasma processing apparatus 10 may further include a controller Cnt. The controller Cnt may be a computer including, for example, a processor, a storage unit, an input device, and a display device. The controller Cnt controls each unit of the plasma processing apparatus 10. In the controller Cnt, the operator is capable of performing, for example, an input operation of a command to manage the plasma processing apparatus 10 using an input device. In addition, in the controller Cnt, the operation situation of the plasma processing apparatus 10 may be visualized and displayed by the display device. Furthermore, the storage unit of the controller Cnt stores a control program and recipe data for controlling various processes executed by the plasma processing apparatus 10 by a processor. The method MT is executed by the plasma processing apparatus 10 when the processor of the controller Cnt executes the control program to control each unit of the plasma processing apparatus 10 according to the recipe data.

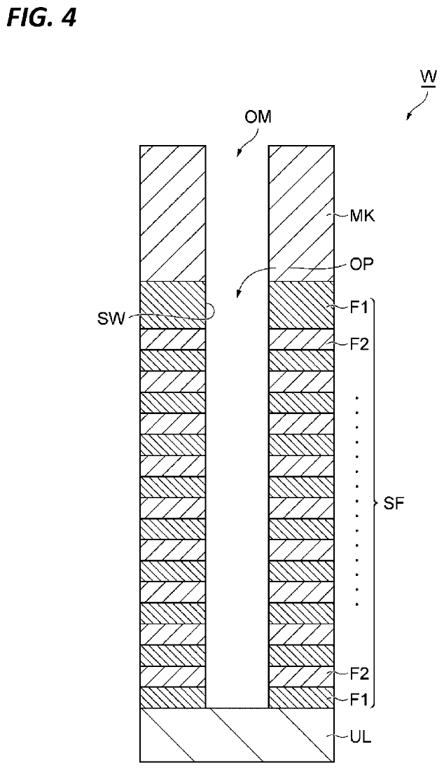

Referring back to FIG. 1, the method MT will be described with reference to the case where the plasma processing apparatus 10 is used as an example. However, the plasma processing apparatus used for executing the method MT is not limited to the plasma processing apparatus 10. In the following description, reference is made to FIG. 4 in addition to FIG. 1. FIG. 4 is a partially enlarged cross-sectional view illustrating an exemplary workpiece after the etching method illustrated in FIG. 1 was applied thereto.

As described above, in step ST1 of the method MT, a workpiece W is provided in the chamber body 12 of the plasma processing apparatus 10. The workpiece W is placed on the electrostatic chuck 20 of the stage 14 in the internal space 12s. The workpiece W is held by the electrostatic chuck 20.

Next, in the method MT, step ST2 is executed. In step ST2, a silicon-containing film SF is etched in the chamber body 12 of the plasma processing apparatus 10. In step ST2, the plasma of a processing gas is generated in the internal space 12s. In step ST2, the silicon-containing film SF is etched by chemical species such as ions and/or radicals from the plasma of the processing gas.

The processing gas used in step ST2 contains carbon and iodine heptafluoride (IF₇). The processing gas used in step ST2 may further contain fluorine. In an embodiment, the processing gas may include a gas containing iodine heptafluoride (IF₇), that is, an iodine heptafluoride gas (IF₇ gas). In an embodiment, the ratio of the flow rate of IF₇ gas to the total flow rate of the processing gas may be set to a ratio of 1.3% or more. In an embodiment, the processing gas may further include a carbon-containing gas in addition to the IF₇ gas. The carbon-containing gas may be a hydrocarbon gas such as, for example, CH₄ gas. In an embodiment, the processing gas may further include a fluorine-containing gas in addition to the IF₇ gas. The fluorine-containing gas may be a fluorocarbon gas and/or a hydrofluorocarbon gas. The fluorocarbon gas is, for example, CF₄ gas or C₄F₈ gas. The hydrofluorocarbon gas is, for example, CHF₃ gas, CH₂F₂ gas, or CH₃F gas. In an embodiment, the processing gas may further include a hydrogen-containing gas. The hydrogen-containing gas is, for example, H₂ gas. In an embodiment, the processing gas may further include an additive gas. The additive gas will be described later.

In step ST2, the controller Cnt executes the control of the gas supply GS so as to supply the processing gas to the internal space 12s. In step ST2 of an embodiment, the controller Cnt adjusts the ratio of the flow rate of the IF₇ gas to the total flow rate of the processing gas supplied into the chamber body 12 to a ratio of 1.3% or more. In step ST2, the controller Cnt executes the control of the exhaust apparatus 50 so as to set the pressure of the internal space 12s to a designated pressure. In addition, in step ST2, the controller Cnt executes the control of the first radio-frequency power supply 62 and the second radio-frequency power supply 64 so as to supply the first radio-frequency waves and the second radio-frequency waves to the lower electrode 18. In addition, the first radio-frequency waves may be supplied to the upper electrode 30 rather than the lower electrode 18.

Furthermore, in step ST2, the temperature of the workpiece W may be adjusted by supplying the coolant to the flow path 18f. The temperature of the workpiece W is set to a temperature of, for example, 0° C. or lower in step ST2. In order to adjust the temperature of the workpiece W, the controller Cnt is capable of controlling the chiller unit.

In step ST2, the plasma of the processing gas is generated in the internal space 12s. In step ST2, the silicon-containing film SF is etched in the film thickness direction by active species (ions and/or radicals) of fluorine from plasma. As a result of execution of step ST2, as illustrated in FIG. 4, an opening OP is formed in the silicon-containing film SF. The opening OP is defined by a side wall surface SW of the silicon-containing film SF formed by etching.

During the execution of step ST2, the side wall surface SW is protected by a protective material. The protective material includes an iodide such as, for example, silicon iodide formed of silicon in the silicon-containing film SF and iodine in the processing gas. This protective material is highly resistant to the active species of fluorine. Therefore, according to the method MT, the lateral etching of the silicon-containing film SF is suppressed.

In an embodiment, the temperature of the workpiece W is set to a temperature of 0° C. or lower during the execution of step ST2. The radicals of fluorine are active species capable of chemically and isotropically etching silicon-containing film SF, but, when the temperature of the workpiece W is set to a temperature of 0° C. or lower, the reaction between the radicals of fluorine and the silicon-containing film SF is suppressed. Therefore, the lateral etching of the silicon-containing film SF is further suppressed.

When the mask MK contains carbon, iodine in the processing gas reacts with carbon and fluorine to form a volatile compound during the execution of step ST2. Therefore, the blocking of the opening of the mask MK is suppressed. Alternatively, when the mask MK contains tungsten, the etching of the mask MK by fluorine is suppressed, and the change in the shape of the mask MK in step ST2 is suppressed.

As mentioned above, the processing gas contains carbon. During the execution of step ST2, the mask MK is etched by forming a volatile compound by the reaction of iodine in the processing gas with carbon and fluorine, but a deposit containing carbon is formed on the mask. As a result, the reduction of the mask MK is suppressed.

In an embodiment, step ST2 may include step ST21 and step ST22. In step ST21, the plasma of the above-described processing gas containing a fluorine-containing gas and IF₇ gas is generated in the chamber body 12, and the silicon-containing film SF is partially etched by chemical species from the plasma. In step ST21, the processing gas does not contain an additive gas. Alternatively, in step ST21, the processing gas contains the additive gas at a ratio smaller than the ratio of the additive gas in the processing gas in step ST22. Hereinafter, the processing gas used in step ST21 may be referred to as a first processing gas.

In this embodiment, the controller Cnt executes a first control and a second control to execute step ST2. In order to execute step ST21, the controller Cnt executes the first control. In the first control, the controller Cnt causes the gas supply GS to supply the first processing gas into the chamber body 12. In the other points, the first control is the same as the control described above for the execution of step ST2.

In the subsequent step ST21, the plasma of the above-described processing gas containing a fluorine-containing gas and IF₇ gas is generated in the chamber body 12, and the silicon-containing film SF is further etched by chemical species from the plasma. In step ST22, the processing gas contains an additive gas. When the processing gas used in step ST21, that is, the first processing gas contains an additive gas, the processing gas used in step ST22 contains the additive gas at a ratio higher than that of the additive gas in the first processing gas.

In order to execute step ST22, the controller Cnt executes the second control. In the second control, the controller Cnt causes the gas supply GS to supply the second processing gas into the chamber body 12. In the other points, the second control is the same as the control described above for the execution of step ST2.

The additive gas contains molecules containing fluorine. The bonding energy of fluorine in the molecules in the additive gas is lower than the bonding energy of fluorine in the molecules in the fluorine-containing gas contained in the processing gas (the first processing gas and the second processing gas). Here, the bonding energy of carbon and fluorine in CF₄ is 453 kJ/mol. The bonding energy of sulfur and fluorine in SF₆ is 327 kJ/mol. The bonding energy of nitrogen and fluorine in NF₃ is 272 kJ/mol. The bonding energy between fluorine and fluorine in F₂ is 154 kJ/mol. Therefore, as an example, when a fluorine-containing gas in the processing gas is CF₄ gas, SF₆ gas, NF₃ gas, or F₂ gas may be used as the additive gas.

When the depth of the opening formed in the silicon-containing film SF is increased by the etching in step ST21, it becomes difficult for the active species of fluorine to reach the deep portion of the opening, and the etching rate decreases. In step ST22, an additive gas is added to the processing gas to suppress a decrease in the etching rate. The additive gas generates fluorine active species having a small mass more than the fluorine-containing gas in the processing gas. The fluorine active species having a small mass is likely to reach a deep point in the opening. Therefore, by transferring the processing from step ST21 to step ST22, the decrease in the etching rate of the silicon-containing film SF is suppressed.

In an embodiment, step ST22 is performed when the aspect ratio of the opening formed in the silicon-containing film SF is 40 or more. In other words, step ST21 is executed in a period in which the opening having the aspect ratio of less than 40 is formed in the silicon-containing film SF. For example, when the time length of the execution period of step ST21 becomes a predetermined time length, the processing is transferred from step ST21 to step ST22. In this embodiment, when the aspect ratio of the opening formed in the silicon-containing film SF is 40 or more, the controller Cnt executes the second control. For example, when the time length of the execution period of the first control becomes the predetermined time length, the controller Cnt terminates the first control and initiates the execution of the second control.

In another embodiment, spectrum data representative of the spectrum of emission of plasma generated in the internal space 12s during the execution of the step ST21 is acquired by the spectroscopic analyzer 74. Then, the timing of transition from step ST21 to step ST22 is determined based on the emission intensity of a wavelength corresponding to silicon specified from the spectrum data (hereinafter, referred to as “emission intensity of silicon”). Specifically, when it is determined that silicon is not released from the silicon-containing film SF based on the emission intensity of silicon, the processing is transferred from step ST21 to step ST22, and step ST22 is initiated. In this embodiment, the controller Cnt uses the emission intensity of silicon in the spectrum data acquired by the spectroscopic analyzer 74 during the execution of the first control to determine the timing of transition from the first control to the second control. The controller Cnt initiates the second control at the determined timing.

The wavelength corresponding to silicon is, for example, 221.1 nm, 221.2 nm, 221.7 nm, 250.7 nm, 251.6 nm, 252.4 nm, 252.9 nm, or 288.2 nm. In an embodiment, when the emission intensity of silicon becomes equal to or less than a reference value, the processing is transferred from step ST21 to step ST22. In a more specific example, argon gas of several sccm is added to the processing gas, and during the execution of step ST21, the ratio of the emission intensity of silicon to the emission intensity of a wavelength corresponding to argon (hereinafter referred to as “emission intensity of argon”) is obtained. When the acquired ratio falls to about 50% or less of the average of the ratio for 30 sec after the initiation of the execution of step ST21, the processing is transferred from step ST21 to step ST22. The wavelength corresponding to argon is, for example, 738.4 nm, 750.4 nm, 763.5 nm, or 811.5 nm. By obtaining the ratio described above, that is, the value obtained by dividing the emission intensity of silicon by the emission intensity of argon, it is possible to obtain a parameter representative of the emission intensity derived from the active species independent of the state of plasma. In addition, instead of the emission intensity of silicon, the emission intensity corresponding to the wavelength of silicon fluoride (SiF), which is a reaction product, may be used. The wavelength corresponding to silicon fluoride is, for example, 436.8 nm, 440.1 nm, or 443.0 nm.

While various embodiments have been described above, various omissions, substitutions, and changes may be made without being limited to the embodiments described above. In addition, it is possible to combine elements in different embodiments to form other embodiments. For example, the silicon-containing film SF may be a single film formed of silicon oxide or silicon nitride. The plasma processing apparatus used to execute the method MT may be any plasma processing apparatus such as, for example, an inductively coupled plasma processing apparatus or a plasma processing apparatus that generates plasma by surface waves such as microwaves.

A simulation performed for the evaluation of the method MT will be described below. In the simulation, a relationship between the temperature of a silicon oxide film and the etching rate of the silicon oxide film by fluorine radicals was obtained. Specifically, the etching rate E_{SiO2} (Angstrom/min) of the silicon oxide film was obtained by the following Equation (1).

E_{SiO2}=0.61×10⁻¹²_{nFS}T^{1/2}e-^{1892/T} (1)

In Equation (1), nFS is the density of fluorine atoms (cm⁻³), and T (K) is the temperature of the silicon oxide film.

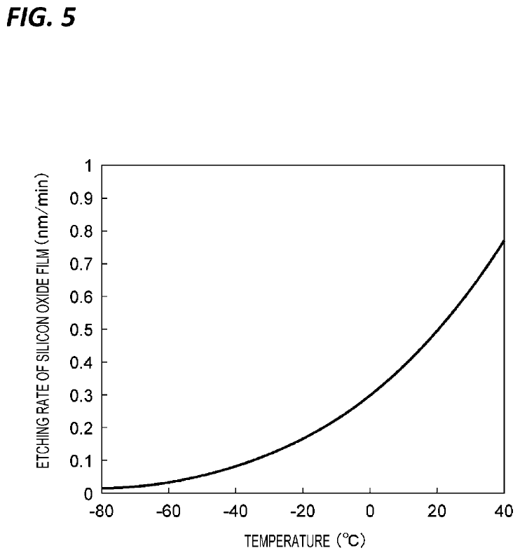

FIG. 5 is a graph representing a simulation result. In the graph of FIG. 5, the horizontal axis represents the temperature of the silicon oxide film, and the vertical axis represents the etching rate of the silicon oxide film. As represented in FIG. 5, the etching rate of the silicon oxide film by fluorine radicals is considerably small when the temperature of the silicon oxide film is 0° C. or lower. Therefore, it has been confirmed that, when the temperature of the workpiece W having a silicon-containing film SF is set to a temperature of 0° C. or lower, the reaction between the silicon-containing film SF and the fluorine radicals capable of laterally etching the silicon-containing film SF is suppressed.

Hereinafter, tests conducted for evaluation of the method MT will be described. The contents of the present disclosure are not limited by the tests described below.

(First Test)

In the first test, the silicon-containing film SF of each of three workpieces W illustrated in FIG. 2 was etched using the plasma processing apparatus 10. In the first test, the silicon-containing films SF were etched under three conditions in which the ratios of the flow rate of IF₇ gas to the total flow rate of the processing gas were different from each other. The ratios of the flow rate of IF₇ gas to the total flow rate in the processing gas were 1.3%, 1.8%, and 2.3% under the three conditions, respectively. The other conditions of the first test are represented below.

<Condition of First Test>
Pressure internal space of chamber 12: 20 mTorr (2.666 Pa)
First radio-frequency waves: 40 MHz, 4.5 kW
Second radio-frequency waves: 0.4 MHz, 5 kW
Processing gas: Mixed gas of CF₄ gas, H₂ gas, O₂ gas, and IF₇ gas
Temperature of electrostatic chuck: −50° C.
Processing time length: 600 sec

As a first comparative test, the silicon-containing film SF of a workpiece W illustrated in FIG. 2 was etched using the plasma processing apparatus 10. In the first comparative test, a mixed gas including CF₄ gas, H₂ gas, and O₂ gas was used. The flow rate of each gas in the mixed gas was a flow rate optimized to suppress the lateral etching amount of the silicon-containing film SF as much as possible. The other conditions of the first comparative test were the same as the corresponding conditions of the first test.

In each of the first test and the first comparative experiment, the maximum width of the opening formed in the silicon-containing film SF by etching was obtained. As a result of the first test, the maximum widths were 96.3 nm, 97.0 nm, and 92.0 when the flow rate ratios of IF₇ gas were 1.3%, 1.8%, and 2.3%, respectively. Meanwhile, as a result of the first comparative test, the maximum width was 108 nm. Therefore, it was confirmed that it is possible to effectively suppress the lateral etching of the silicon-containing film SF when IF₇ gas is contained in the processing gas. In addition, it was confirmed that the amount of lateral etching of the silicon-containing film SF is further reduced when the ratio of the flow rate of the IF₇ gas to the total flow rate of the processing gas is increased in the range of 1.3% or more.

(Second Test)

In the second test, the silicon-containing film SF of each of two workpieces W illustrated in FIG. 2 was etched using the plasma processing apparatus 10. In the second test, the ratio of the flow rate of IF₇ gas to the total flow rate of the processing gas was 1.3%. In the second test, the silicon-containing films SF were etched under two conditions having different processing time lengths. The processing time lengths were 600 sec and 1200 sec under the two conditions, respectively. The other conditions of the second test are represented below.

<Condition of Second Test>
Pressure internal space of chamber 12: 20 mTorr (2.666 Pa)
First radio-frequency waves: 40 MHz, 4.5 kW
Second radio-frequency waves: 0.4 MHz, 5 kW
Processing gas: Mixed gas of CF₄ gas, H₂ gas, NF₃ gas, and IF₇ gas
Temperature of electrostatic chuck: −50° C.

As a second comparative test, the silicon-containing film SF of each of two workpieces W illustrated in FIG. 2 was etched using the plasma processing apparatus 10. In the second comparative test, a mixed gas containing CF₄ gas, H₂ gas, NF₃ gas, and HI gas was used as the processing gas. In the second comparative test, the ratio of the flow rate of HI gas to the total flow rate of the processing gas was 1.7%. In the second comparative test, the silicon-containing films SF were etched under two conditions having different processing time lengths. The processing time lengths were 600 sec and 1020 sec under the two conditions, respectively. The other conditions of the second comparative test were the same as the corresponding conditions of the second test.

In each of the first test and the first comparative experiment, the maximum width of the opening formed in the silicon-containing film SF by etching was obtained. As a result of the second test, when the processing time length was 600 sec, the depth and the maximum width of the opening were 4342 nm and 95.6 nm, respectively. In addition, as a result of second test, when the processing time length was 1200 sec, the depth and the maximum width of the opening were 6610 nm and 106 nm, respectively. In addition, as a result of second comparative test, when the processing time length was 600 sec, the depth and the maximum width of the opening were 4027 nm and 99.4 nm, respectively. In addition, as a result of second comparative test, when the processing time length was 1020 sec, the depth and the maximum width of the opening were 6460 nm and 114 nm, respectively. Therefore, it was confirmed that, when a processing gas including IF₇ gas is used, the lateral etching of the silicon-containing film SF is effectively suppressed even if the depth of the opening formed in silicon-containing film SF is deep compared to using a processing gas including HI gas.

In each of the second test and the second comparative test, an SEM photograph of a cross section of an etched workpiece W was obtained. According to the acquired SEM photographs, it was confirmed that when the processing gas including IF₇ gas is used, the amount of residue adhering to the side wall surface that defines the opening formed in the silicon-containing film SF is significantly reduced, compared to using the processing gas including HI gas.

As described above, in the etching of a silicon-containing film, it is possible to further suppress the lateral etching of the silicon-containing film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a workpiece having a silicon-containing film and a mask having an opening formed therein and provided on the silicon-containing film in a chamber body of a plasma processing apparatus; and
(b) generating plasma of a processing gas containing carbon and iodine heptafluoride in the chamber body thereby etching the silicon containing film.

2. The etching method according to claim 1, wherein the processing gas includes iodine heptafluoride gas.

3. The etching method according to claim 2, wherein a ratio of a flow rate of the iodine heptafluoride gas to a total flow rate of the processing gas supplied into the chamber body in (b) is 1.3% or more.

4. The etching method according to claim 1, wherein the processing gas further contains fluorine.

5. The etching method according to claim 1, wherein (b) includes:
(b1) partially etching the silicon-containing film by the plasma of the processing gas including a fluorine-containing gas, and
(b2) further etching the silicon-containing film by the plasma of the processing gas further including an additive gas,
wherein the additive gas contains molecules including fluorine, and bonding energy of the fluorine in the molecules included in the additive gas is lower than bonding energy of fluorine in molecules in the fluorine-containing gas.

6. The etching method according to claim 5, wherein (b2) is performed when an aspect ratio of the opening formed in the silicon-containing film is 40 or more.

7. The etching method according to claim 5, wherein (b2) is performed when it is determined that no silicon is released from the silicon-containing film based on emission intensity of a wavelength corresponding silicon of emission of the plasma generated in the chamber body during (b1).

8. The etching method according to claim 1, wherein the silicon-containing film is formed of at least one of silicon oxide and silicon nitride.

9. The etching method according to claim 8, wherein the silicon-containing film includes a plurality of silicon oxide films and a plurality of silicon nitride films, which are alternately stacked.

10. The etching method according to claim 1, wherein the mask contains carbon.

11. The etching method according to claim 1, wherein the mask contains tungsten.

12. A plasma processing apparatus comprising:
a chamber body;
a support provided in the chamber body;
a gas supply source configured to supply a processing gas containing carbon and iodine heptafluoride into the chamber body;
a radio-frequency power supply configured to supply radio-frequency power to excite the processing gas; and
a controller configured to control the gas supply source and the radio-frequency power supply,
wherein the controller is configured to: execute a control of the gas supply to supply the processing gas into the chamber body to etch a silicon-containing film of a workpiece disposed on the support by generating plasma of the processing gas, and execute a control of the radio-frequency power supply to supply the radio-frequency power.

13. The plasma processing apparatus according to claim 12, wherein the processing gas includes iodine heptafluoride gas.

14. The plasma processing apparatus according to claim 13, wherein, in the control of the gas supply, the controller adjusts a ratio of a flow rate of the iodine heptafluoride gas to a total flow rate of the processing gas supplied into the chamber body to 1.3% or more.

15. The plasma processing apparatus according to claim 12, wherein the processing gas further contains fluorine.

16. The plasma processing apparatus according to claim 12, wherein the controller is configured to:
execute a first control that causes the gas supply source to supply the processing gas including a fluorine-containing gas into the chamber body, and
subsequently execute a second control that causes the gas supply source to supply the processing gas further including an additive gas into the chamber body, and
wherein the additive gas contains molecules including fluorine, and bonding energy of the fluorine in the molecules included in the additive gas is lower than bonding energy of fluorine in molecules in the fluorine-containing gas.

17. The plasma processing apparatus according to claim 16, wherein the controller is configured to execute the second control when an aspect ratio of an opening formed in the silicon-containing film is 40 or more.

18. The plasma processing apparatus according to claim 16, wherein the controller is configured to initiate the second control when determined that no silicon is released from the silicon-containing film based on emission intensity of a wavelength corresponding silicon of emission of the plasma generated in the chamber body during execution of the first control.
